(19) United States
(12) Patent Application Publication
(10) Pub. No.: US 2020/0303306 A1
(43) Pub. Date: Sep. 24, 2020

(54) SEMICONDUCTOR DEVICE

(71) Applicants: Kabushiki Kaisha Toshiba, Minato-ku (JP); Toshiba Electronic Devices & Storage Corporation, Minato-ku (JP)

(72) Inventor: Toshiaki Shirai, Narashino (JP)

(73) Assignees: Kabushiki Kaisha Toshiba, Minato-ku (JP); Toshiba Electronic Devices & Storage Corporation, Minato-ku (JP)

(21) Appl. No.: 16/556,405

(22) Filed: Aug. 30, 2019

(30) Foreign Application Priority Data
Mar. 19, 2019 (JP) 2019-050648

(51) Int. Cl. H01L 23/528; H01L 23/00

(52) U.S. Cl. CPC H01L 23/5286; H01L 24/05; H01L 2224/13026; H01L 2224/0401; H01L 2224/05025; H01L 24/13

(57) ABSTRACT

According to one embodiment, there is provided a semiconductor device configured such that area pads or bumps are placed in a lattice shape on a mounting surface and interconnect layers are stacked in an inside of the device. The device includes power switches for power supply shutdown, the power switches being placed in a lowermost layer of the interconnect layers at positions directly under the area pads or bumps, and metal interconnects for power supply, the metal interconnects being stacked and formed in a region under the area pads or bumps in a manner to penetrate signal interconnect layers, and being connected to the power switches, thus forming a columnar structure.

### CROSS-REFERENCE TO RELATED APPLICATIONS

This application is based upon and claims the benefit of priority from Japanese Patent Application No. 2019-050648, filed Mar. 19, 2019, the entire contents of which are incorporated herein by reference.

### FIELD

Embodiments described herein relate generally to a semiconductor device.

### BACKGROUND

There have been proposed many technologies relating to a semiconductor integrated circuit of an area bump configuration, in which low power control is executed.

In a semiconductor integrated circuit of an area pad and area bump configuration, power supply pads and power supply bumps are placed, not on four sides of a chip die but on an entire area of an uppermost layer in a lattice shape. In this semiconductor integrated circuit, such a technology that, in units of a functional block that is a target of power supply shutdown, power switches for power supply shutdown are placed under a lowermost layer along an outside frame of each block, has been put to practical use. Besides, such a technology that power switches are placed in a row direction at such selected positions as not to affect circuitry in the functional block, has been put to practical use.

In addition, in a semiconductor integrated circuit having a multiple metal layer configuration, a budget of density ratio between a power supply metal and a virtual power supply metal becomes nonuniform in an attempt to decrease an interconnect resistance, in particular, in an upper-side power supply interconnect layer, in a range from area pads or bumps to power switches, this resulting in a factor of a voltage drop in the virtual power supply.

### BRIEF DESCRIPTION OF THE DRAWINGS

FIG. 1 is a perspective view illustrating, in an extracted manner, a configuration of a part of a semiconductor integrated circuit according to an embodiment; and

FIG. 2 is a plan view which exemplarily illustrates a configuration of a ball grid array (BGA) corresponding to a function shutdown block of a part of the semiconductor integrated circuit according to the embodiment.

### DETAILED DESCRIPTION

Hereinafter, embodiments will be described with reference to the accompanying drawings.

In general, according to one embodiment, there is provided a semiconductor device configured such that area pads or bumps are placed in a lattice shape on a mounting surface and interconnect layers are stacked in an inside of the semiconductor device. The semiconductor device includes: power switches for power supply shutdown, the power switches being placed in a lowermost layer of the interconnect layers at positions directly under the area pads or bumps; and metal interconnects for power supply, the metal interconnects being stacked and formed in a region under the area pads or bumps in a manner to penetrate signal interconnect layers, and being connected to the power switches, thus forming a columnar structure.

Referring to the drawings, a case will be described below, in which an embodiment is applied to a semiconductor integrated circuit using a surface-mount package of a ball grid array (BGA).

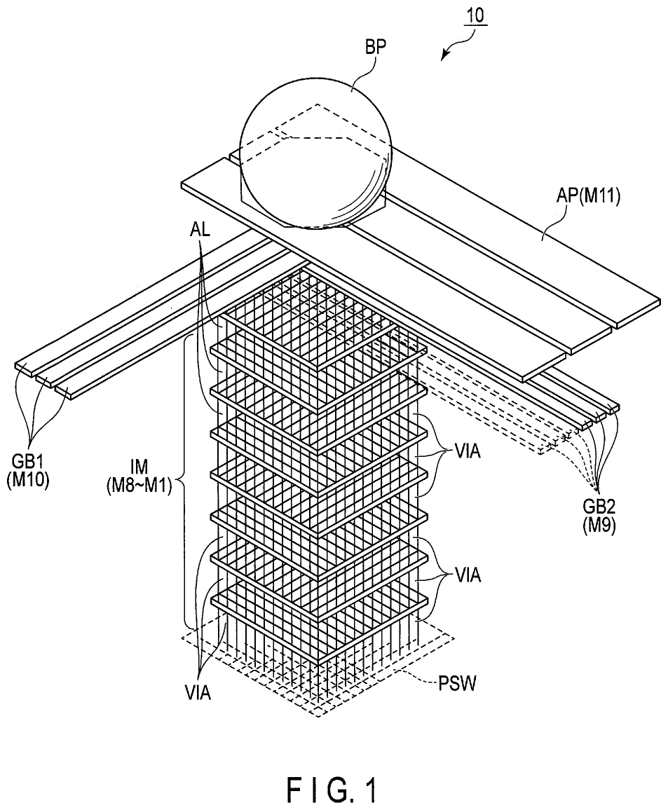

FIG. 1 is a perspective view illustrating, in an extracted manner, a configuration of a very small part of a semiconductor integrated circuit 10 according to the embodiment. In FIG. 1, it is assumed that in the semiconductor integrated circuit 10, a metal ball BP using a solder or the like, which serves as an area pad or bump, is located above in the Figure. In addition, one of many metal balls BP, which are placed in a lattice shape on an entire area of a mounting surface of the semiconductor integrated circuit 10, is selected, and the relationship between the metal ball BP and interconnect layers, which constitute a semiconductor chip located directly below the metal ball BP, is illustrated in an extracted manner. Thus, the depiction of a printed wiring board on which a semiconductor chip is mounted and sealed, and the depiction of insulation films or the like between interconnect layers, are omitted.

In FIG. 1, such a multilayer configuration is formed that a plurality of layers constituting a semiconductor chip, for example, eleven interconnect layers M11 to M1, are placed under the metal ball BP, and power switches PSW for power supply shutdown are placed under these layers.

The metal ball BP is formed on an area pad or bump position with one side of, e.g. 100 [μm]. On the other hand, the power switches PSW are configured by many power switch cells each having one side of, e.g. 5 [μm], which are placed in an array.

The eleven interconnect layers M11 to M1 are composed of, from the metal ball BP side, an uppermost layer AP (M11), a first global layer GB1 (M10), a second global layer GB2 (M9), and intermediate layers IM (M8 to M1).

The uppermost layer AP, first global layer GB1 and second global layer GB2 are composed of power supply interconnect layers, the routing directions of wiring of which are perpendicular to each other between mutually neighboring layers to form a mesh structure.

In the uppermost layer AP (M11), power supply interconnects each having an interconnect width of, for example, about ⅓ to ¼ of the width of the metal ball BP, are successively assigned in parallel. In the first global layer GB1 (M10), power supply interconnects each having a less interconnect width, that is, an interconnect width of, for example, about ⅓ to ¼ of the interconnect width of the upper most layer AP, are successively assigned in parallel. In the second global layer GB2 (M9), power supply interconnects each having a still less interconnect width, that is, an interconnect width of, for example, about ⅓ to ¼ of the interconnect width of the first global interconnect GB1, are successively assigned in parallel.

The intermediate layers IM are located between the metal ball BP and power switches PSW, as illustrated in FIG. 1. Each of the intermediate layers IM constitutes a signal interconnect layer on which various elements, circuitry, etc. are mounted.

Note that, for the purpose of easier description, the depiction in FIG. 1 is not based on actual dimensions of interconnect width, etc.

In each signal interconnect layer of the intermediate layers IM (MS to M1), power supply interconnects are assigned such that routing directions of wiring are perpendicular to each other between mutually neighboring layers. Further, many access vias (metal interconnects for power supply) VIA are formed by a power supply via stack structure in which plug-shaped connection portions are stacked so as to connect upper and lower layers with respect to each kind of actual power supply interconnects, for example, power supply interconnects VDD, ground interconnects VSS and virtual power supply interconnects VDDV.

For example, the width of the power supply interconnect in the signal interconnect layer is about ⅕ to 1/20 of the interconnect width in the second global layer GB2. Plug-shaped connection portions, each having a surface width of about 1/20 to 1/40 of the interconnect width of the power supply interconnect of each signal interconnect layer of the intermediate layers IM (M8 to M1), are formed for the power supply interconnects of the signal interconnect layers of the intermediate layers IM (M8 to M1). Many access vias VIA are formed by such structures that the plug-shaped connection portions, which are placed at regular intervals in the routing direction of wiring on each identical power supply interconnect, are stacked.

Thus, in a region directly under the metal ball BP that is the area pad or bump, many access vias VIA are formed and stacked in a manner to penetrate the intermediate layers IM (M8 to M1), and are connected to the power switches PSW, thus forming a columnar structure corresponding the size of the area pad or bump.

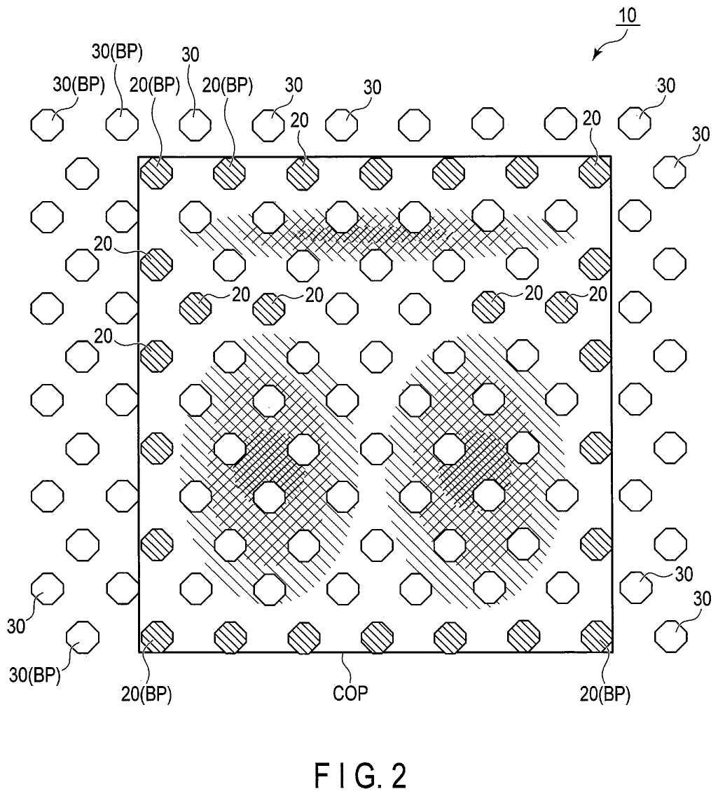

FIG. 2 is a plan view which exemplarily illustrates a configuration of a BGA corresponding to a function shutdown block COP of a part of the semiconductor integrated circuit 10, and a configuration of a part under the BGA. Hatched parts denoted by reference sign 20(BP) in FIG. 2 are the metal balls BP, directly under which the power switches PSW as illustrated in FIG. 1 are placed. On the other hand, parts denoted by reference sign 30 are the metal balls BP, directly under which the power switches PSW as illustrated in FIG. 1 are not placed.

As illustrated in FIG. 2, the metal balls 20, directly under which the power switches PSW are placed, are placed along the outer frame of the function shutdown block COP. In addition, the metal balls 20, directly under which the power switches PSW are placed, are also placed at a row position slightly on an upper side of the center of the function shutdown block COP in FIG. 2.

The latter metal balls 20 are placed at positions that are free from restrictions relating to power supply control of a memory, a logical core circuit, etc. in the function shutdown block COP.

In FIG. 2, hatchings indicate degrees of a voltage decrease of a virtual power supply, which occurs in each area where the metal ball BP is formed, mainly in a range from the power switches PSW to the central side of the region of the function shutdown block COP. In FIG. 2, a part with a high density of hatching indicates a part with a high degree of the voltage decrease.

By minimizing the interconnect resistance from the part, where the metal ball 20(BP) is placed, to the power switches PSW directly below the metal ball 20(BP), and by minimizing the resistance in the via connection portions which constitute the intermediate layers IM, the voltage decrease of the virtual power supply can be decreased while the influence on interconnects is minimized.

As has been described above, according to the embodiment, there can be provided a semiconductor device which can reduce the voltage drop in the virtual power supply, by holding down the interconnect resistance in the interconnects between the metal balls BP that are area pads or bumps and the power switches PSW, and in the connection vias which constitute the intermediate layers IM.

In addition, in the present embodiment, the structures illustrated in FIG. 1 are placed at positions along the frame of the function shutdown block COP which divides interconnect layers, and at positions in the inside of the frame, which are free from restrictions relating to the power supply control. Therefore, the configuration of the power supply control of the functional block can be optimized, and useless power consumption can be reduced.

In the embodiment, the power switches PSW are placed in an array and connected in the region corresponding to the metal ball BP that is the area pad or bump. It is also conceivable that, while the power switches PSW are placed at positions along the frame of the region corresponding to the metal balls BP, an electro-static discharge (ESD) protection element for protecting the semiconductor integrated circuit 10 against static electricity, which may possibly be applied, for example, from the outside, is placed in the region inside the frame.

Besides, in the present embodiment, the case was described in which the surface-mount package is implemented by the BGA. The embodiment, however, is also applicable to a semiconductor device with a configuration using pads, pins or the like, instead of metal balls BP, as electrodes that constitute the area pads or bumps placed in a lattice shape on the entire area of the mounting surface.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made. The accompanying claims and their equivalents are intended to cover such forms or modifications as would fall within the scope of the inventions.

1. A semiconductor device configured such that area pads or bumps are placed in a lattice shape on a mounting surface and interconnect layers are stacked in an inside of the semiconductor device, the semiconductor device comprising:
power switches for power supply shutdown, the power switches being placed in a lowermost layer of the interconnect layers at positions directly under the area pads or bumps; and
metal interconnects for power supply, the metal interconnects being stacked and formed in a region under the area pads or bumps in a manner to penetrate signal interconnect layers, and being connected to the power switches, thus forming a columnar structure.

2. The semiconductor device according to claim 1, further comprising:
a power supply interconnect layer placed above the signal interconnect layers, and placed between the signal interconnect layers and the area pads or bumps.

3. The semiconductor device according to claim 1, wherein the power switches are placed at positions along a frame of a functional block region which divides the interconnect layers, and at positions in an inside of the frame, which are free from restrictions relating to power supply control.

4. The semiconductor device according to claim 1, wherein the power switches are placed at positions along a frame of a functional block region which divides the interconnect layers, and an element for protecting the semiconductor device against static electricity is placed at a position in an inside of the frame, the position being free from restrictions relating to power supply control.

5. The semiconductor device according to claim 1, wherein the power switches are configured by power switch cells placed in an array.

6. The semiconductor device according to claim 1, wherein in the signal interconnect layers, power supply interconnects are assigned such that routing directions of wiring are perpendicular to each other between mutually neighboring layers.
